(19) United States
(12) Patent Application Publication
(10) Pub. No.: US 2024/0043024 A1
(43) Pub. Date: Feb. 8, 2024

(54) GENERATION OF ORIGINAL SIMULATIONS

(71) Applicant: GM Cruise Holdings LLC, San Francisco, CA (US)

(72) Inventors: Kartikeya Shukla, Mountain View, CA (US); Jyothidhar Pulakunta, Dublin, CA (US)

(21) Appl. No.: 17/881,426

(22) Filed: Aug. 4, 2022

(51) Int. Cl. B60W 50/06; B60W 60/00; B60W 50/02; G06F 30/27

(52) U.S. Cl. CPC B60W 50/06; B60W 60/001; B60W 50/0205; B60W 50/0225; G06F 30/27; B60W 2556/10

(57) ABSTRACT

System, methods, and computer-readable media for a random simulation scenario generator for training autonomous vehicle (AV) systems that can generate a plurality of simulation scenarios based on an input that designates a required common attribute or attributes. The random simulation scenario generator includes a trained machine-learning model that takes the input that designates a required common attribute or attributes and outputs a plurality of simulation scenarios that includes the required common attribute or attributes.

### TECHNICAL FIELD

The subject technology relates to generating original simulations for an autonomous vehicle (AV), and more specifically, generating original simulations having at least one specified attribute from a trained machine-learning model.

### BACKGROUND

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system.

Autonomous vehicles may be tested using simulations. Simulations for testing autonomous vehicles may be created manually.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying drawings in which:

FIG. 1 illustrates an example flowchart of a trained machine-learning network that can produce an original simulation scenario having at least one specified attribute, according to some examples of the present disclosure;

FIG. 2 illustrates an example method for training the machine-learning model for generating the original simulation scenario, according to some examples of the present disclosure;

FIG. 3 illustrates an example method for receiving an original simulation scenario having at least one specified attribute from a trained machine-learning model, according to some examples of the present disclosure;

FIG. 4 illustrates an example system environment that can be used to facilitate autonomous vehicle (AV) dispatch and operations, according to some aspects of the disclosed technology;

FIG. 5 illustrates an example of a deep learning neural network that can be used to implement a perception module and/or one or more validation modules, according to some aspects of the disclosed technology; and

FIG. 6 illustrates an example processor-based system with which some aspects of the subject technology can be implemented.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

The disclosed technology addresses the need in the art for a random simulation scenario generator for training autonomous vehicle (AV) systems that can generate a plurality of simulation scenarios based on an input that designates a required common attribute or attributes. The random simulation scenario generator includes a trained machine-learning model that takes the input that designates a required common attribute or attributes and outputs a plurality of simulation scenarios that includes the required common attribute or attributes.

The random simulation scenario generator may also incorporate randomly introducing faults to the AV as well as randomized behavior from actors in the scene. For example, for randomized faults, the AV components and synthetic sensor models for Light Detection and Ranging (LiDAR), Radio Detection and Ranging (RADAR), camera data, such as special settings for different weather conditions, such as heavy snow and slippery roads, may be turned on and off randomly to predict how the AV would behave. For example, if the LiDAR stops working and sensor data is not being collected, and then a random biker jumps in front of the AV in a simulated scene, how the AV would handle the scenario can be reviewed and analyzed. The randomized faults may be part of the random scenario simulation or may later be added via a randomized faults service.

Simulations typically are based on scenarios that have happened to an AV of a fleet of AVs used to collect data and how the AV responded. However, in such cases, simulations may be limited to what has actually happened in the real world in those limited sets of scenarios. In order to mix-and-match different aspects of different real-world scenarios, simulations can be manually created. However, doing so can be resource-intensive, especially when a large number of edge-case scenarios are needed to test the AV's behavior. Therefore, it would be advantageous to have an original simulation scenario generator to generate original scenes that take components from actual real-world scenarios using a machine-learning model. The machine-learning model may also randomly introduce faults of the AV in addition to plausible behaviors of other actors in the scene. Since the machine-learning model is trained based on a dataset from real-world scenarios, the outputted original scenes will also have aspects from the real-world scenarios.

The present technology is beneficial for automatically and efficiently creating unique and original simulation scenarios that include specified characteristics. For example, if the AV needs more training on how to handle a double-parked UPS truck, the present technology can generate unique scenes including the double-parked UPS truck. The present technology is not only more efficient in generating such scenes, but it can also offer more variety in output scenes than a human who might be limited by biases or their innate creativity in generating a scene for simulation.

The simulation data can be useful for reinforcement learning, which may include identifying which dangerous scenarios need to be focused on and whether the AV should stop in a safe place or reach out for remote assistance in such scenarios. Reinforcement learning can also help with identifying areas that need to be further stress tested and what tests are needed.

The random simulation scenario generator for an autonomous vehicle of the present technology solves at least these problems and provides other benefits as will be apparent from the figures and description provided herein.

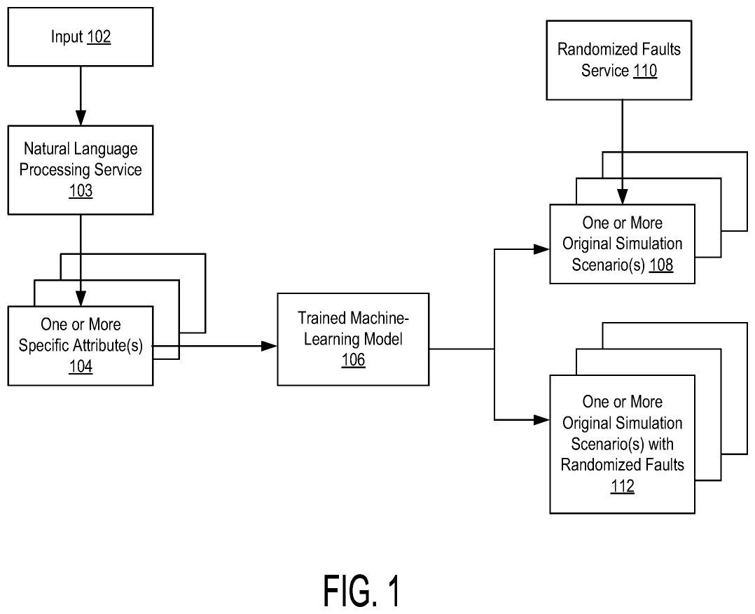

FIG. 1 illustrates an example flowchart 100 for producing an original simulation scenario having at least one specified attribute, according to some examples of the present disclosure. An input 102 may be provided, such as via a client device. The input 102 may be a phrase or sentence that is provided in natural language and be processed by a natural language processing service 103 that determines keywords from the input 102. The input 102 may describe required components for a plurality of original scenarios, such as requiring “a biker traveling perpendicular to the AV” somewhere in the scene. The keywords extracted may be “biker” and “perpendicular” and correlated with a respective specific attribute from a lexicon database for a list of attributes. In such a case, the one or more specific attributes 104 may be a “perpendicular biker” and may be provided to a trained machine-learning model 106.

The trained machine-learning model 106 may then output a plurality of original simulation scenarios, with each original simulation scenario including the one or more specified attributes 104 along with other randomized features. In some cases, the trained machine-learning model 106 outputs a plurality of original simulation scenarios 108 that does not include randomly turned-off AV components and synthetic sensor models, and such features can later be added using a randomized faults service 110. In some cases, the trained machine-learning model 106 outputs a plurality of original simulation scenarios 112 that include randomly turned-off AV components and synthetic sensor models as part of each simulation scenario.

For example, continuing from the example above, each of the original simulation scenarios 108 would include a biker traveling perpendicular to the AV and other random attributes, such as other cars, pedestrians, sidewalks, crosswalks, etc. In contrast, each of the original simulation scenarios 112 includes the biker traveling perpendicular to the AV, other random attributes, as well as randomized failures of AV components or synthetic sensor models.

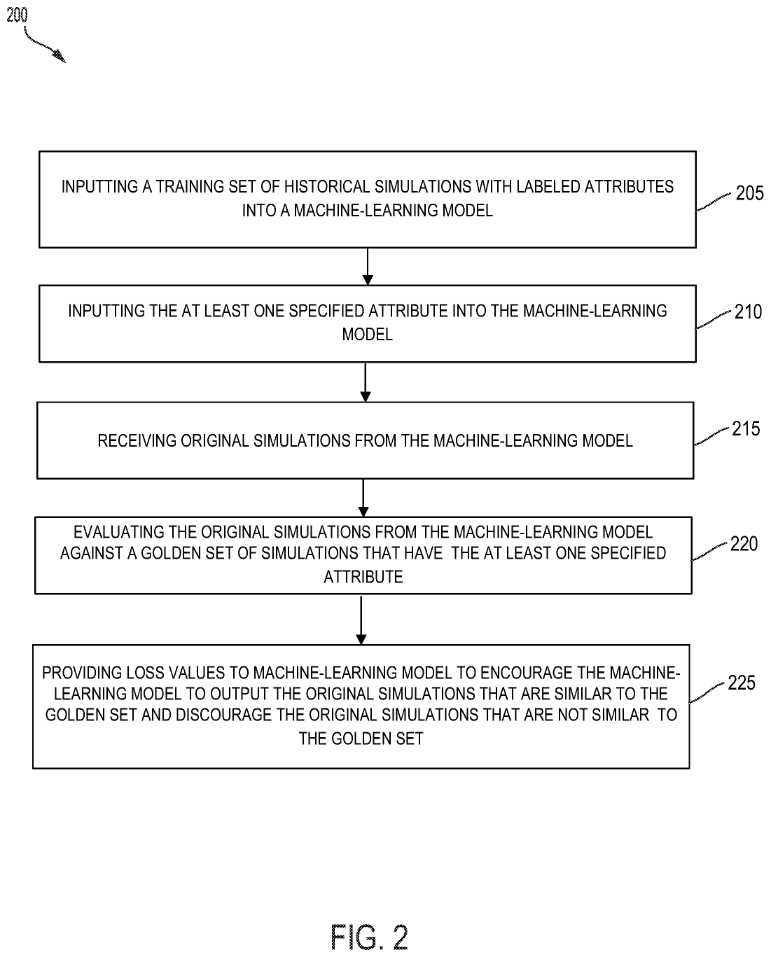

FIG. 2 illustrates an example method 200 for training a machine-learning model for generating the original simulation scenario, according to some examples of the present disclosure. In this setup, based on supervised learning, a machine-learning model trains on a set of labeled training data in order to learn how to output original simulation scenes. The machine-learning model may be trained with a training set of historical simulations with labeled attributes. The training set may be from real driving data accumulated from a fleet of AVs recording their surroundings as they drove through various environments. The attributes appearing in their environments may be labeled by humans or automatically. To get labeled training data, human annotators are often relied on to label examples for the model to train on. In some cases, creating a simulation may require coming up with the parameters, creating the simulation code associated with the parameters, such as in a YAML file, checking it into GitHub, pushing it, and then going through various build processes, which can take a long time. As systems become more mature, higher volumes of labeled data may be produced by leveraging automation and relying on large operational workforces. In some cases, the training set may include millions of scenarios.

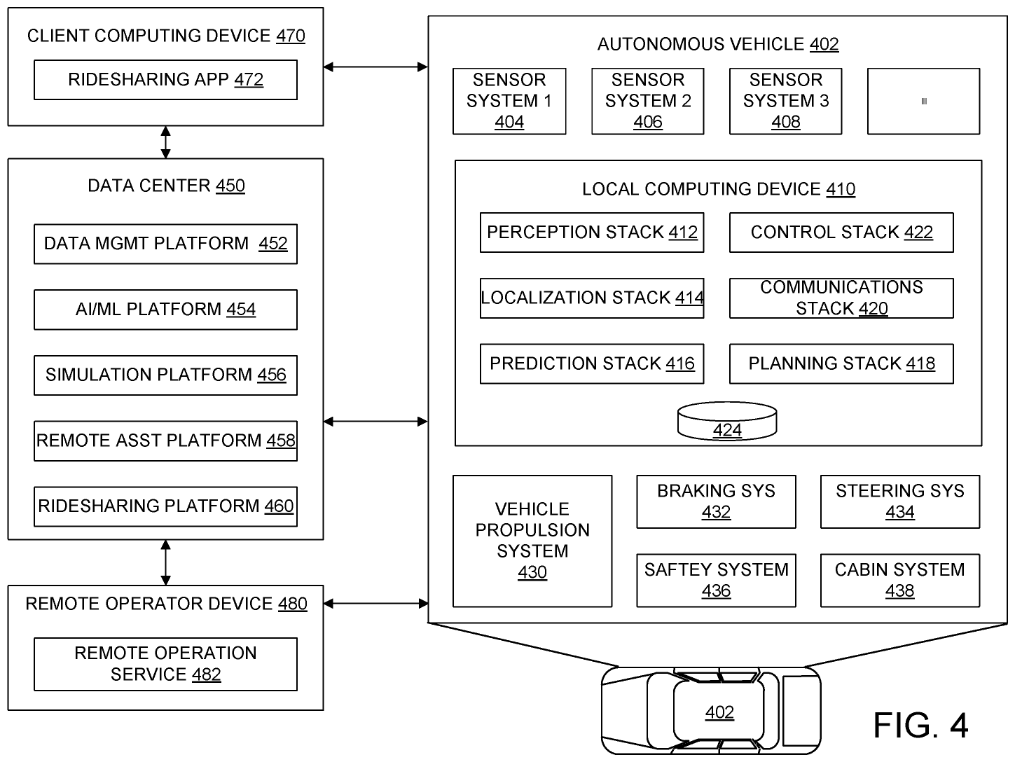

The training set of historical simulations with labeled attributes may be inputted into the machine-learning model, at step 205. In addition, the at least one specified attribute may be inputted into the machine-learning model, at step 210. For example, the AI/ML platform 454, illustrated in FIG. 4, may input the training set of historical simulations with the labeled attributes and the at least one specified attribute.

The machine-learning model may receive the training set of historical simulations and the at least one specified attribute and provide original simulations based on the training set of historical simulations and the at least one specified attribute. The original simulations may be received from the machine-learning model at step 215. The outputted original simulation may be evaluated against a golden set of simulations wherein each simulation has the least one specified attribute, in step 220. For example, the AI/ML platform 454, illustrated in FIG. 4, may receive the original simulations and evaluates the original simulations. Each simulation of the golden set of historical simulations includes the at least one specified attribute. The golden set is considered “golden” because it is accepted as the most accurate and reliable of its kind, in that they all have the at least one specified attribute in common while having randomized other attributes.

In some cases, loss values may be provided to the machine-learning model to encourage the machine-learning model to output original simulations that are similar to the golden set and discourage the original simulations that are not similar to the golden set, in step 225. For example, the AI/ML platform 454, illustrated in FIG. 4, may provide the loss values. In some cases, the training of the machine-learning model may include a plurality of iterations, wherein each iteration sets a different first subset of a plurality of historical simulations as labeled inputs and a different second subset of the plurality of historical simulations as the golden set, and the machine-learning model is trained to output original simulations similar to the golden set, which include the at least one specific attribute.

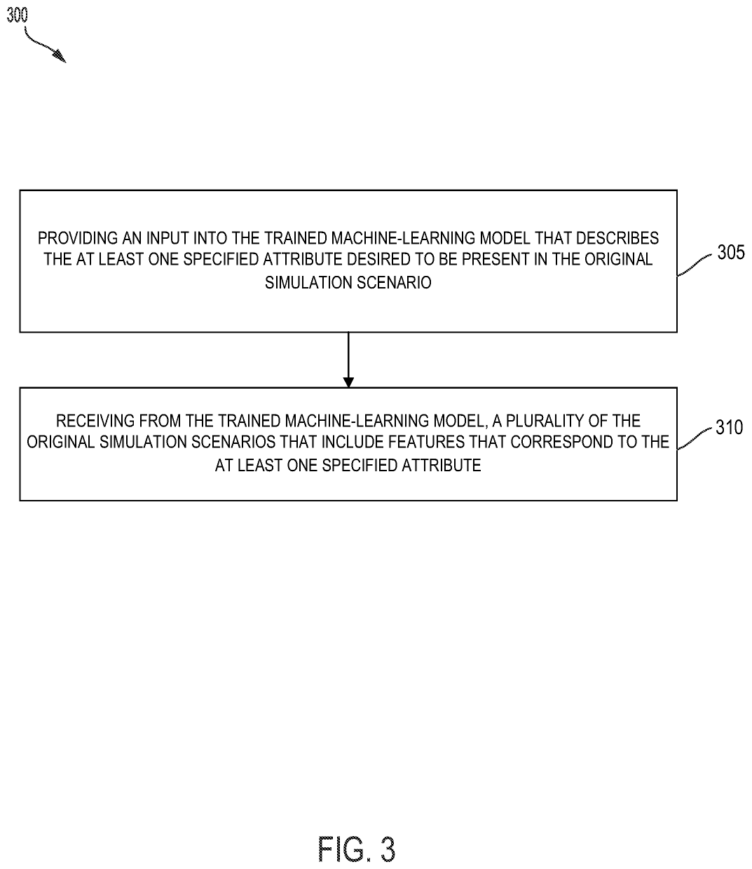

FIG. 3 illustrates an example method 300 for receiving a simulation scenario having at least one specified attribute from a trained machine-learning model, according to some examples of the present disclosure. Once the machine-learning model has been trained, an input may be provided to the trained machine-learning model, in step 305. In some cases, the input describes the at least one specified attribute desired to be present in the original simulation scenario. For example, the AI/ML platform 454, illustrated in FIG. 4, may provide the input to the trained machine-learning model.

Then, a plurality of original simulation scenarios that include features that correspond to the at least one specific attribute is received from the trained machine-learning model, in step 310. In some cases, the input may include two or more specified attributes. In some cases, the two or more attributes are selected based on the received input that describes the two or more attributes, and the trained machine-learning model outputs original simulations based on the two or more attributes, and the original simulations include the two or more attributes. For example, if the input was “bikes and orange traffic cones” then each original simulation should include both a bike and orange traffic cones as well as other randomized attributes.

In some cases, simulations may be executed using the plurality of original simulation scenarios for an autonomous vehicle control stack to navigate. In such cases, other attributes in the original simulations may include a failed function of an autonomous vehicle control stack or an input into the autonomous vehicle control stack while the autonomous vehicle control stack is navigating the respective original simulation. The failed function of an autonomous vehicle control stack may be a failure of the perception stack 412 or the localization stack 414 due to simulated failures of LiDAR sensors or RADAR sensors, for example. The input of the autonomous vehicle control may be associated with what code the AV is running on based on what inputs the AV was provided. In other words, randomizing what is happening internally to the AV as well as externally to test the various scenarios an AV may experience.

Alternatively, the failed function can be separately introduced to original simulations that do not have such failed functions as part of the simulation via the randomized faults service 110. Then, based on results from the simulations, an area that needs focus may be determined based on simulated responses by the autonomous vehicle. For example, the AV may not be as equipped to deal with emergency vehicles when LiDAR sensors are malfunctioning. In such a case, learning that perhaps relying on other stacks and sensors of the AV as back-up would be a useful outcome.

Furthermore, in some cases, the inputted at least specific attribute may include the failed function of an autonomous vehicle control stack or an adjustment of the autonomous vehicle control stack while the autonomous vehicle control stack is navigating the original simulation scenarios. For example, if the plurality of original simulation scenarios that are required include a rainy environment while having a failed special setting for slippery roads turned off such that the AV is tested in various environments under such conditions.

Turning now to FIG. 4, this figure illustrates an example of an AV management system 400. One of ordinary skill in the art will understand that, for the AV management system 400 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 400 includes an AV 402, a data center 450, and a client computing device 470. The AV 402, the data center 450, and the client computing device 470 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 402 can navigate about roadways without a human driver based on sensor signals generated by multiple sensor systems 404, 406, and 408. The sensor systems 404-408 can include different types of sensors and can be arranged about the AV 402. For instance, the sensor systems 404-408 can comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 404 can be a camera system, the sensor system 406 can be a LIDAR system, and the sensor system 408 can be a RADAR system. Other embodiments may include any other number and type of sensors.

AV 402 can also include several mechanical systems that can be used to maneuver or operate AV 402. For instance, the mechanical systems can include vehicle propulsion system 430, braking system 432, steering system 434, safety system 436, and cabin system 438, among other systems. Vehicle propulsion system 430 can include an electric motor, an internal combustion engine, or both. The braking system 432 can include an engine brake, a wheel braking system (e.g., a disc braking system that utilizes brake pads), hydraulics, actuators, and/or any other suitable componentry configured to assist in decelerating AV 402. The steering system 434 can include suitable componentry configured to control the direction of movement of the AV 402 during navigation. Safety system 436 can include lights and signal indicators, a parking brake, airbags, and so forth. The cabin system 438 can include cabin temperature control systems, in-cabin entertainment systems, and so forth. In some embodiments, the AV 402 may not include human driver actuators (e.g., steering wheel, handbrake, foot brake pedal, foot accelerator pedal, turn signal lever, window wipers, etc.) for controlling the AV 402. Instead, the cabin system 438 can include one or more client interfaces (e.g., Graphical User Interfaces (GUIs), Voice User Interfaces (VUIs), etc.) for controlling certain aspects of the mechanical systems 430-438.

AV 402 can additionally include a local computing device 410 that is in communication with the sensor systems 404-408, the mechanical systems 430-438, the data center 450, and the client computing device 470, among other systems. The local computing device 410 can include one or more processors and memory, including instructions that can be executed by the one or more processors. The instructions can make up one or more software stacks or components responsible for controlling the AV 402; communicating with the data center 450, the client computing device 470, and other systems; receiving inputs from riders, passengers, and other entities within the AV's environment; logging metrics collected by the sensor systems 404-408; and so forth. In this example, the local computing device 410 includes a perception stack 412, a mapping and localization stack 414, a planning stack 416, a control stack 418, a communications stack 420, an High Definition (HD) geospatial database 422, and an AV operational database 424, among other stacks and systems.

Perception stack 412 can enable the AV 402 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 404-408, the mapping and localization stack 414, the HD geospatial database 422, other components of the AV, and other data sources (e.g., the data center 450, the client computing device 470, third-party data sources, etc.). The perception stack 412 can detect and classify objects and determine their current and predicted locations, speeds, directions, and the like. In addition, the perception stack 412 can determine the free space around the AV 402 (e.g., to maintain a safe distance from other objects, change lanes, park the AV, etc.). The perception stack 412 can also identify environmental uncertainties, such as where to look for moving objects, flag areas that may be obscured or blocked from view, and so forth.

Mapping and localization stack 414 can determine the AV's position and orientation (pose) using different methods from multiple systems (e.g., GPS, IMUs, cameras, LIDAR, RADAR, ultrasonic sensors, the HD geospatial database 422, etc.). For example, in some embodiments, the AV 402 can compare sensor data captured in real-time by the sensor systems 404-408 to data in the HD geospatial database 422 to determine its precise (e.g., accurate to the order of a few centimeters or less) position and orientation. The AV 402 can focus its search based on sensor data from one or more first sensor systems (e.g., GPS) by matching sensor data from one or more second sensor systems (e.g., LIDAR). If the mapping and localization information from one system is unavailable, the AV 402 can use mapping and localization information from a redundant system and/or from remote data sources.

The planning stack 416 can determine how to maneuver or operate the AV 402 safely and efficiently in its environment. For example, the planning stack 416 can receive the location, speed, and direction of the AV 402, geospatial data, data regarding objects sharing the road with the AV 402 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 402 from one point to another. The planning stack 416 can determine multiple sets of one or more mechanical operations that the AV 402 can perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 416 can select from multiple backup plans to carry out. For example, while preparing to change lanes to turn right at an intersection, another vehicle may aggressively cut into the destination lane, making the lane change unsafe. The planning stack 416 could have already determined an alternative plan for such an event, and upon its occurrence, help to direct the AV 402 to go around the block instead of blocking a current lane while waiting for an opening to change lanes.

The control stack 418 can manage the operation of the vehicle propulsion system 430, the braking system 432, the steering system 434, the safety system 436, and the cabin system 438. The control stack 418 can receive sensor signals from the sensor systems 404-408 as well as communicate with other stacks or components of the local computing device 410 or a remote system (e.g., the data center 450) to effectuate operation of the AV 402. For example, the control stack 418 can implement the final path or actions from the multiple paths or actions provided by the planning stack 416. This can involve turning the routes and decisions from the planning stack 416 into commands for the actuators that control the AV's steering, throttle, brake, and drive unit.

The communication stack 420 can transmit and receive signals between the various stacks and other components of the AV 402 and between the AV 402, the data center 450, the client computing device 470, and other remote systems. The communication stack 420 can enable the local computing device 410 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 420 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 422 can store HD maps and related data of the streets upon which the AV 402 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

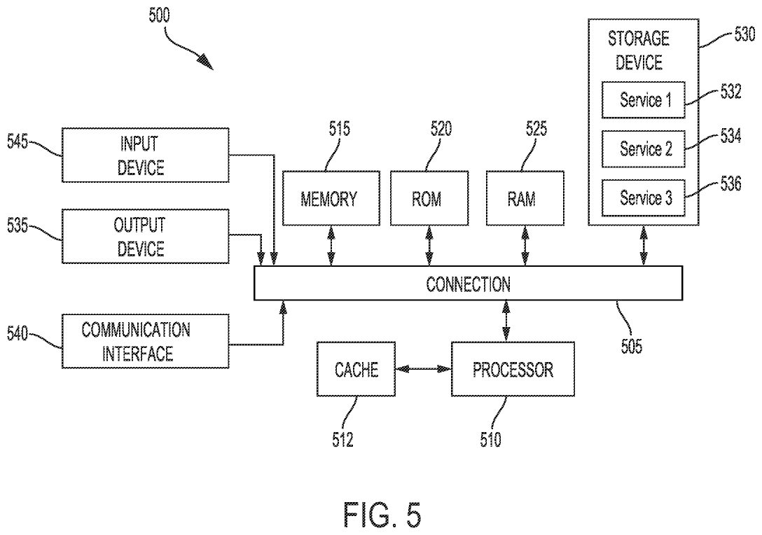

The AV operational database 424 can store raw AV data generated by the sensor systems 404-408 and other components of the AV 402 and/or data received by the AV 402 from remote systems (e.g., the data center 450, the client computing device 470, etc.). In some embodiments, the raw AV data can include HD LIDAR point cloud data, image or video data, RADAR data, GPS data, and other sensor data that the data center 450 can use for creating or updating AV geospatial data as discussed further below with respect to FIG. 5 and elsewhere in the present disclosure.

The data center 450 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 450 can include one or more computing devices remote to the local computing device 410 for managing a fleet of AVs and AV-related services. For example, in addition to managing the AV 402, the data center 450 may also support a ridesharing service, a delivery service, a remote/roadside assistance service, street services (e.g., street mapping, street patrol, street cleaning, street metering, parking reservation, etc.), and the like.

The data center 450 can send and receive various signals to and from the AV 402 and the client computing device 470. These signals can include sensor data captured by the sensor systems 404-408, roadside assistance requests, software updates, ridesharing pick-up and drop-off instructions, and so forth. In this example, the data center 450 includes one or more of a data management platform 452, an Artificial Intelligence/Machine-learning (AI/ML) platform 454, a simulation platform 456, a remote assistance platform 458, a ridesharing platform 460, and a map management platform 462, among other systems.

Data management platform 452 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 450 can access data stored by the data management platform 452 to provide their respective services.

The AI/ML platform 454 can provide the infrastructure for training and evaluating machine-learning algorithms for operating the AV 402, the simulation platform 456, the remote assistance platform 458, the ridesharing platform 460, the map management platform 462, and other platforms and systems. Using the AI/ML platform 454, data scientists can prepare data sets from the data management platform 452; select, design, and train machine-learning models; evaluate, refine, and deploy the models; maintain, monitor, and retrain the models; and so on.

The simulation platform 456 can enable testing and validation of the algorithms, machine-learning models, neural networks, and other development efforts for the AV 402, the remote assistance platform 458, the ridesharing platform 460, the map management platform 462, and other platforms and systems. The simulation platform 456 can replicate a variety of driving environments and/or reproduce original scenarios from data captured by the AV 402, including rendering geospatial information and road infrastructure (e.g., streets, lanes, crosswalks, traffic lights, stop signs, etc.) obtained from the map management platform 462; modeling the behavior of other vehicles, bicycles, pedestrians, and other dynamic elements; simulating inclement weather conditions, different traffic scenarios; and so on.

The remote assistance platform 458 can generate and transmit instructions regarding the operation of the AV 402. For example, in response to an output of the AI/ML platform 454 or other system of the data center 450, the remote assistance platform 458 can prepare instructions for one or more stacks or other components of the AV 402.

The ridesharing platform 460 can interact with a customer of a ridesharing service via a ridesharing application 472 executing on the client computing device 470. The client computing device 470 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general purpose computing device for accessing the ridesharing application 472. The client computing device 470 can be a customer's mobile computing device or a computing device integrated with the AV 402 (e.g., the local computing device 410). The ridesharing platform 460 can receive requests to be picked up or dropped off from the ridesharing application 472 and dispatch the AV 402 for the trip.

Map management platform 462 can provide a set of tools for the manipulation and management of geographic and spatial (geospatial) and related attribute data. The data management platform 452 can receive LIDAR point cloud data, image data (e.g., still image, video, etc.), RADAR data, GPS data, and other sensor data (e.g., raw data) from one or more AVs 402, Unmanned Aerial Vehicles (UAVs), satellites, third-party mapping services, and other sources of geospatially referenced data. The raw data can be processed, and map management platform 462 can render base representations (e.g., tiles (2D), bounding volumes (3D), etc.) of the AV geospatial data to enable users to view, query, label, edit, and otherwise interact with the data. Map management platform 462 can manage workflows and tasks for operating on the AV geospatial data. Map management platform 462 can control access to the AV geospatial data, including granting or limiting access to the AV geospatial data based on user-based, role-based, group-based, task-based, and other attribute-based access control mechanisms. Map management platform 462 can provide version control for the AV geospatial data, such as to track specific changes that (human or machine) map editors have made to the data and to revert changes when necessary. Map management platform 462 can administer release management of the AV geospatial data, including distributing suitable iterations of the data to different users, computing devices, AVs, and other consumers of HD maps. Map management platform 462 can provide analytics regarding the AV geospatial data and related data, such as to generate insights relating to the throughput and quality of mapping tasks.

In some embodiments, the map viewing services of map management platform 462 can be modularized and deployed as part of one or more of the platforms and systems of the data center 450. For example, the AI/ML platform 454 may incorporate the map viewing services for visualizing the effectiveness of various object detection or object classification models, the simulation platform 456 may incorporate the map viewing services for recreating and visualizing certain driving scenarios, the remote assistance platform 458 may incorporate the map viewing services for replaying traffic incidents to facilitate and coordinate aid, the ridesharing platform 460 may incorporate the map viewing services into the client application 472 to enable passengers to view the AV 402 in transit en route to a pick-up or drop-off location, and so on.

In some embodiments, a remote operator device 480 may be used to present an interface for a remote operator of the drive-through calibration process. The remote operator device 480 may interface with the data center 450 and/or the AV 402 to perform the various checks and/or to stop and stop the drive-through calibration data collection process performed on the AV 402. As mentioned previously, the remote operation service 482 may locally run at the remote operator device 480, at the data center 450, or in a separate server that the remote operator device 480 accesses.

FIG. 5 illustrates an example processor-based system with which some aspects of the subject technology can be implemented. For example, processor-based system 500 can be any computing device making up, or any component thereof in which the components of the system are in communication with each other using connection 505. Connection 505 can be a physical connection via a bus, or a direct connection into processor 510, such as in a chipset architecture. Connection 505 can also be a virtual connection, networked connection, or logical connection.

In some embodiments, computing system 500 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 500 includes at least one processing unit (Central Processing Unit (CPU) or processor) 510 and connection 605 that couples various system components including system memory 515, such as Read-Only Memory (ROM) 520 and Random-Access Memory (RAM) 525 to processor 510. Computing system 500 can include a cache of high-speed memory 512 connected directly with, in close proximity to, or integrated as part of processor 510.

Processor 510 can include any general-purpose processor and a hardware service or software service, such as services 532, 534, and 536 stored in storage device 530, configured to control processor 510 as well as a special-purpose processor where software instructions are incorporated into the actual processor design. Processor 510 may essentially be a completely self-contained computing system, containing multiple cores or processors, a bus, memory controller, cache, etc. A multi-core processor may be symmetric or asymmetric.

To enable user interaction, computing system 500 includes an input device 545, which can represent any number of input mechanisms, such as a microphone for speech, a touch-sensitive screen for gesture or graphical input, keyboard, mouse, motion input, speech, etc. Computing system 500 can also include output device 535, which can be one or more of a number of output mechanisms known to those of skill in the art. In some instances, multimodal systems can enable a user to provide multiple types of input/output to communicate with computing system 500. Computing system 500 can include communications interface 540, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 540 may also include one or more Global Navigation Satellite System (GNSS) receivers or transceivers that are used to determine a location of the computing system 500 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 530 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 530 can include software services, servers, services, etc., that when the code that defines such software is executed by the processor 510, it causes the system 500 to perform a function. In some embodiments, a hardware service that performs a particular function can include the software component stored in a computer-readable medium in connection with the necessary hardware components, such as processor 510, connection 505, output device 535, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

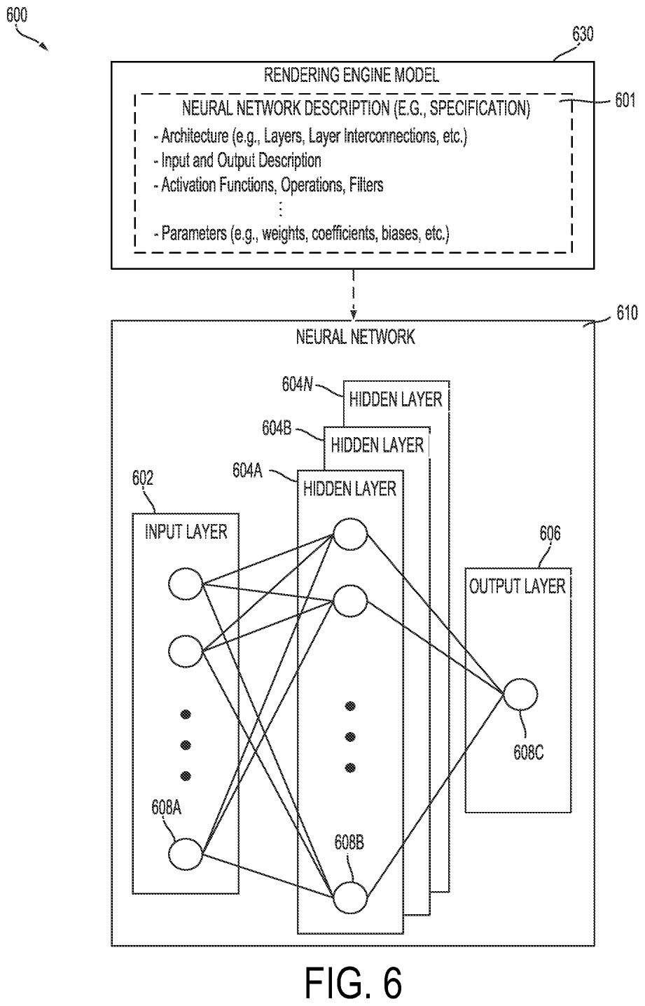

FIG. 6 illustrates an example neural network architecture, in accordance with some aspects of the present technology. Architecture 600 includes a neural network 610 defined by an example neural network description 601 in rendering engine model (neural controller) 630. The neural network 610 can represent a neural network implementation of a rendering engine for rendering media data. The neural network description 601 can include a full specification of the neural network 610, including the neural network architecture 600. For example, the neural network description 601 can include a description or specification of the architecture 600 of the neural network 610 (e.g., the layers, layer interconnections, number of nodes in each layer, etc.); an input and output description which indicates how the input and output are formed or processed; an indication of the activation functions in the neural network, the operations or filters in the neural network, etc.; neural network parameters such as weights, biases, etc.; and so forth.

The neural network 610 reflects the architecture 600 defined in the neural network description 601. In this example, the neural network 610 includes an input layer 602, which includes input data, information about objects (e.g., AV 402) in an environment as perceived by sensors 404, 406, 408 of the AV 402. In one illustrative example, the input layer 602 can include data representing a portion of the input media data such as a patch of data or pixels (e.g., a 128×128 patch of data) in an image corresponding to the input media data (e.g., that of AV 402 and the environment).

The neural network 610 includes hidden layers 604A through 604N (collectively “604” hereinafter). The hidden layers 604 can include n number of hidden layers, where n is an integer greater than or equal to one. The number of hidden layers can include as many layers as needed for a desired processing outcome and/or rendering intent. The neural network 610 further includes an output layer 606 that provides an output (e.g., paths that are outputted to a trained planning algorithm) resulting from the processing performed by the hidden layers 604. In one illustrative example, the output layer 606 can provide paths that are most likely to occur and a path that is considered an object collision path.

The neural network 610 in this example is a multi-layer neural network of interconnected nodes. Each node can represent a piece of information. Information associated with the nodes is shared among the different layers and each layer retains information as information is processed. In some cases, the neural network 610 can include a feed-forward neural network, in which case there are no feedback connections where outputs of the neural network are fed back into itself. In other cases, the neural network 610 can include a recurrent neural network, which can have loops that allow information to be carried across nodes while reading in input.

Information can be exchanged between nodes through node-to-node interconnections between the various layers. Nodes of the input layer 602 can activate a set of nodes in the first hidden layer 604A. For example, as shown, each of the input nodes of the input layer 602 is connected to each of the nodes of the first hidden layer 604A. The nodes of the hidden layer 604A can transform the information of each input node by applying activation functions to the information. The information derived from the transformation can then be passed to and can activate the nodes of the next hidden layer (e.g., 604B), which can perform their own designated functions. Example functions include convolutional, up-sampling, data transformation, pooling, and/or any other suitable functions. The output of the hidden layer (e.g., 604B) can then activate nodes of the next hidden layer (e.g., 604N), and so on. The output of the last hidden layer can activate one or more nodes of the output layer 606, at which point an output is provided. In some cases, while nodes (e.g., nodes 608A, 608B, 608C) in the neural network 610 are shown as having multiple output lines, a node has a single output and all lines shown as being output from a node represent the same output value.

In some cases, each node or interconnection between nodes can have a weight that is a set of parameters derived from training the neural network 610. For example, an interconnection between nodes can represent a piece of information learned about the interconnected nodes. The interconnection can have a numeric weight that can be tuned (e.g., based on a training dataset), allowing the neural network 610 to be adaptive to inputs and able to learn as more data is processed.

The neural network 610 can be pre-trained to process the features from the data in the input layer 602 using the different hidden layers 604 in order to provide the output through the output layer 606. In an example in which the neural network 610 is used to identify an object collision path from a trained object path prediction algorithm, the neural network 610 can be trained using training data that includes example objects (e.g., AV 402) in an environment as perceived by sensors 104-108 of the AV 402. For instance, training images can be input into the neural network 610, which can be processed by the neural network 610 to generate outputs which can be used to tune one or more aspects of the neural network 610, such as weights, biases, etc.

In some cases, the neural network 610 can adjust weights of nodes using a training process called backpropagation. Backpropagation can include a forward pass, a loss function, a backward pass, and a weight update. The forward pass, loss function, backward pass, and parameter update is performed for one training iteration. The process can be repeated for a certain number of iterations for each set of training media data until the weights of the layers are accurately tuned.

For a first training iteration for the neural network 610, the output can include values that do not give preference to any particular class due to the weights being randomly selected at initialization. For example, if the output is a vector with probabilities that the object includes different product(s) and/or different users, the probability value for each of the different product and/or user may be equal or at least very similar (e.g., for ten possible products or users, each class may have a probability value of 0.1). With the initial weights, the neural network 610 is unable to determine low level features and thus cannot make an accurate determination of what the classification of the object might be. A loss function can be used to analyze errors in the output. Any suitable loss function definition can be used.

The loss (or error) can be high for the first training dataset (e.g., images) since the actual values will be different than the predicted output. The goal of training is to minimize the amount of loss so that the predicted output comports with a target or ideal output. The neural network 610 can perform a backward pass by determining which inputs (weights) most contributed to the loss of the neural network 610, and can adjust the weights so that the loss decreases and is eventually minimized.

A derivative of the loss with respect to the weights can be computed to determine the weights that contributed most to the loss of the neural network 610. After the derivative is computed, a weight update can be performed by updating the weights of the filters. For example, the weights can be updated so that they change in the opposite direction of the gradient. A learning rate can be set to any suitable value, with a high learning rate including larger weight updates and a lower value indicating smaller weight updates.

The neural network 610 can include any suitable neural or deep learning network. One example includes a convolutional neural network (CNN), which includes an input layer and an output layer, with multiple hidden layers between the input and out layers. The hidden layers of a CNN include a series of convolutional, nonlinear, pooling (for downsampling), and fully connected layers. In other examples, the neural network 610 can represent any other neural or deep learning network, such as an autoencoder, a deep belief nets (DBNs), recurrent neural networks (RNNs), etc.

### Selected Examples

Aspect 1. A method for receiving an original simulation scenario having at least one specified attribute from a trained machine-learning model, the method comprising: providing an input into the trained machine-learning model that describes the at least one specified attribute desired to be present in the original simulation scenario; and receiving from the trained machine-learning model, a plurality of original simulation scenarios that include features that correspond to the at least one specified attribute, wherein combinations of other attributes in each original simulation scenario are different from each other.

Aspect 2. The method of Aspect 1, wherein the trained machine-learning model becomes trained by the method comprising: inputting a training set of historical simulations with labeled attributes into a machine-learning model; inputting the at least one specified attribute into the machine-learning model; receiving original simulations from the machine-learning model; evaluating the original simulations from the machine-learning model against a golden set of simulations including the at least one specified attribute; and providing loss values to the machine-learning model to encourage the machine-learning model to output the original simulations that are similar to the golden set and discourage the original simulations that are not similar to the golden set.

Aspect 3. The method of any of Aspects 1 to 2, wherein the input is a phrase or sentence, the method further comprising: determining, via natural language processing, keywords from the input; and correlating each keyword with the at least one specified attribute based on a lexicon database for a list of attributes.

Aspect 4. The method of any of Aspects 1 to 3, wherein the input includes two or more specified attributes selected based on the input that describes the two or more specified attributes, and wherein the trained machine-learning model is trained to output each original simulation to include the two or more specified attributes.

Aspect 5. The method of any of Aspects 1 to 4, wherein the other attributes in the original simulations include at least one of a failed function of an autonomous vehicle control stack or an adjustment of the autonomous vehicle control stack while the autonomous vehicle control stack is navigating the original simulation scenarios.

Aspect 6. The method of any of Aspects 1 to 5, further comprising: executing simulations using the plurality of original simulation scenarios for an autonomous vehicle control stack to navigate.

Aspect 7. The method of any of Aspects 1 to 6, further comprising: failing one or more functions of the autonomous vehicle control stack or adding an adjustment of the autonomous vehicle control stack while the autonomous vehicle control stack is navigating each original simulation scenario.

Aspect 8. The method of any of Aspects 1 to 7, further comprising: based on running the original simulation scenarios, determine a feature that needs improvement based on simulated responses by an autonomous vehicle.

Aspect 9. A non-transitory computer-readable medium comprising instructions, the instructions, when executed by a computing system, cause the computing system to: provide an input into a trained machine-learning model that describes at least one specified attribute desired to be present in an original simulation scenario; and receive from the trained machine-learning model, a plurality of original simulation scenarios that include features that correspond to the at least one specified attribute, wherein combinations of other attributes in each original simulation scenario are different from each other.

Aspect 10. The non-transitory computer-readable medium of Aspect 9, wherein the instructions further cause the computing system to: input a training set of historical simulations with labeled attributes into a machine-learning model; input the at least one specified attribute into the machine-learning model; receive original simulations from the machine-learning model; evaluate the original simulations from the machine-learning model against a golden set of simulations that have the at least one specified attribute; and provide loss values to the machine-learning model to encourage the machine-learning model to output the original simulations that are similar to the golden set and discourage the original simulations that are not similar to the golden set.

Aspect 11. The non-transitory computer-readable medium of any of Aspects 9 to 10, wherein the input is a phrase or sentence, wherein the instructions further cause the computing system to: determine, via natural language processing, keywords from the input; and correlate each keyword with the at least one specified attribute based on a lexicon database for a list of attributes.

Aspect 12. The non-transitory computer-readable medium of Aspects 9 to 11, wherein the input includes two or more specified attributes selected based on the input that describes the two or more specified attributes, and wherein the trained machine-learning model is trained to output each original simulation to include the two or more specified attributes.

Aspect 13. The non-transitory computer-readable medium of Aspects 9 to 12, wherein the other attributes in the original simulations include at least one of a failed function of an autonomous vehicle control stack or an adjustment of the autonomous vehicle control stack while the autonomous vehicle control stack is navigating the original simulation scenarios.

Aspect 14. The non-transitory computer-readable medium of Aspects 9 to 13, wherein the instructions further cause the computing system to: execute simulations using the plurality of original simulation scenarios for an autonomous vehicle control stack to navigate.

Aspect 15. The non-transitory computer-readable medium of Aspects 9 to 14, wherein the instructions further cause the computing system to: fail one or more functions of the autonomous vehicle control stack or adding an adjustment of the autonomous vehicle control stack while the autonomous vehicle control stack is navigating each original simulation scenario.

Aspect 16. The non-transitory computer-readable medium of Aspects 9 to 115, wherein the instructions further cause the computing system to: based on running the original simulation scenarios, determine a feature that needs improvement based on simulated responses by an autonomous vehicle.

Aspect 17. A system comprising: one or more processors; and a non-transitory computer-readable medium storing instructions that, when executed by the one or more processors, cause the one or more processors to: provide an input into a trained machine-learning model that describes at least one specified attribute desired to be present in an original simulation scenario; and receive from the trained machine-learning model, a plurality of original simulation scenarios that include features that correspond to the at least one specified attribute, wherein combinations of other attributes in each original simulation scenario are different from each other.

Aspect 18. The system of Aspect 17, wherein the instructions further cause the one or more processors to: input a training set of historical simulations with labeled attributes into a machine-learning model; input the at least one specified attribute into the machine-learning model; receive original simulations from the machine-learning model; evaluate the original simulations from the machine-learning model against a golden set of simulations that have the at least one specified attribute; and provide loss values to the machine-learning model to encourage the machine-learning model to output the original simulations that are similar to the golden set and discourage the original simulations that are not similar to the golden set.

Aspect 19. The system of Aspects 17 to 18, wherein the instructions further cause the one or more processors to: determine, via natural language processing, keywords from the input; and correlate each keyword with the at least one specified attribute based on a lexicon database for a list of attributes.

Aspect 20. The system of Aspects 17 to 19, wherein the input includes two or more specified attributes selected based on the input that describes the two or more specified attributes, and wherein the trained machine-learning model is trained to output each original simulation to include the two or more specified attributes.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

What is claimed is:

1. A method for receiving an original simulation scenario having at least one specified attribute from a trained machine-learning model, the method comprising:
providing an input into the trained machine-learning model that describes the at least one specified attribute desired to be present in the original simulation scenario; and
receiving from the trained machine-learning model, a plurality of original simulation scenarios that include features that correspond to the at least one specified attribute, wherein combinations of other attributes in each original simulation scenario are different from each other.

2. The method of claim 1, wherein the trained machine-learning model becomes trained by the method comprising:
inputting a training set of historical simulations with labeled attributes into a machine-learning model;
inputting the at least one specified attribute into the machine-learning model;
receiving original simulations from the machine-learning model;
evaluating the original simulations from the machine-learning model against a golden set of simulations including the at least one specified attribute; and
providing loss values to the machine-learning model to encourage the machine-learning model to output the original simulations that are similar to the golden set and discourage the original simulations that are not similar to the golden set.

3. The method of claim 1, wherein the input is a phrase or sentence, the method further comprising:
determining, via natural language processing, keywords from the input; and
correlating each keyword with the at least one specified attribute based on a lexicon database for a list of attributes.

4. The method of claim 1, wherein the input includes two or more specified attributes selected based on the input that describes the two or more specified attributes, and wherein the trained machine-learning model is trained to output each original simulation to include the two or more specified attributes.

5. The method of claim 1, wherein the other attributes in the original simulations include at least one of a failed function of an autonomous vehicle control stack or an adjustment of the autonomous vehicle control stack while the autonomous vehicle control stack is navigating the original simulation scenarios.

6. The method of claim 1, further comprising:
executing simulations using the plurality of original simulation scenarios for an autonomous vehicle control stack to navigate.

7. The method of claim 6, further comprising:
failing one or more functions of the autonomous vehicle control stack or adding an adjustment of the autonomous vehicle control stack while the autonomous vehicle control stack is navigating each original simulation scenario.

8. The method of claim 1, further comprising:
based on running the original simulation scenarios, determine a feature that needs improvement based on simulated responses by an autonomous vehicle.

9. A non-transitory computer-readable medium comprising instructions, the instructions, when executed by a computing system, cause the computing system to:
provide an input into a trained machine-learning model that describes at least one specified attribute desired to be present in an original simulation scenario; and
receive from the trained machine-learning model, a plurality of original simulation scenarios that include features that correspond to the at least one specified attribute, wherein combinations of other attributes in each original simulation scenario are different from each other.

10. The non-transitory computer-readable medium of claim 9, wherein the instructions further cause the computing system to:
input a training set of historical simulations with labeled attributes into a machine-learning model;
input the at least one specified attribute into the machine-learning model;
receive original simulations from the machine-learning model;
evaluate the original simulations from the machine-learning model against a golden set of simulations that have the at least one specified attribute; and
provide loss values to the machine-learning model to encourage the machine-learning model to output the original simulations that are similar to the golden set and discourage the original simulations that are not similar to the golden set.

11. The non-transitory computer-readable medium of claim 9, wherein the input is a phrase or sentence, wherein the instructions further cause the computing system to:
determine, via natural language processing, keywords from the input; and
correlate each keyword with the at least one specified attribute based on a lexicon database for a list of attributes.

12. The non-transitory computer-readable medium of claim 9, wherein the input includes two or more specified attributes selected based on the input that describes the two or more specified attributes, and wherein the trained machine-learning model is trained to output each original simulation to include the two or more specified attributes.

13. The non-transitory computer-readable medium of claim 9, wherein the other attributes in the original simulations include at least one of a failed function of an autonomous vehicle control stack or an adjustment of the autonomous vehicle control stack while the autonomous vehicle control stack is navigating the original simulation scenarios.

14. The non-transitory computer-readable medium of claim 9, wherein the instructions further cause the computing system to:
execute simulations using the plurality of original simulation scenarios for an autonomous vehicle control stack to navigate.

15. The non-transitory computer-readable medium of claim 14, wherein the instructions further cause the computing system to:
fail one or more functions of the autonomous vehicle control stack or adding an adjustment of the autonomous vehicle control stack while the autonomous vehicle control stack is navigating each original simulation scenario.

16. The non-transitory computer-readable medium of claim 11, wherein the instructions further cause the computing system to:
based on running the original simulation scenarios, determine a feature that needs improvement based on simulated responses by an autonomous vehicle.

17. A system comprising:
one or more processors; and
a non-transitory computer-readable medium storing instructions that, when executed by the one or more processors, cause the one or more processors to:
provide an input into a trained machine-learning model that describes at least one specified attribute desired to be present in an original simulation scenario; and
receive from the trained machine-learning model, a plurality of original simulation scenarios that include features that correspond to the at least one specified attribute, wherein combinations of other attributes in each original simulation scenario are different from each other.

18. The system of claim 17, wherein the instructions further cause the one or more processors to:
input a training set of historical simulations with labeled attributes into a machine-learning model;
input the at least one specified attribute into the machine-learning model;
receive original simulations from the machine-learning model;
evaluate the original simulations from the machine-learning model against a golden set of simulations that have the at least one specified attribute; and
provide loss values to the machine-learning model to encourage the machine-learning model to output the original simulations that are similar to the golden set and discourage the original simulations that are not similar to the golden set.

19. The system of claim 17, wherein the instructions further cause the one or more processors to:
determine, via natural language processing, keywords from the input; and
correlate each keyword with the at least one specified attribute based on a lexicon database for a list of attributes.

20. The system of claim 17, wherein the input includes two or more specified attributes selected based on the input that describes the two or more specified attributes, and wherein the trained machine-learning model is trained to output each original simulation to include the two or more specified attributes.
